(19) United States
(12) Patent Application Publication
(10) Pub. No.: US 2008/0074856 A1
(43) Pub. Date: Mar. 27, 2008

(54) Electronic Subassembly

(75) Inventor: Andreas Ostmann, Berlin (DE)

Correspondence Address: KAPLAN GILMAN GIBSON & DERNIER L.L.P., 900 ROUTE 9 NORTH, WOODBRIDGE, NJ, 07095, US

(73) Assignee: Fraunhofer-Gesellschaft Zur Forderung Der Angewandten Forschung e.V.

(21) Appl. No.: 11/850,970

(22) Filed: Sep. 6, 2007

(30) Foreign Application Priority Data
Sep. 13, 2006 (DE) 102006043785.3

(51) Int. Cl. H05K 7/02; H05K 7/14

(52) U.S. Cl. 361/808; 361/807

(57) ABSTRACT

An electronic subassembly having a plurality of components which are connected to each other at least partially for signal- and data exchange, said components having contacts for the supply of electrical energy. One or more components are combined to form a separate radio module which is provided respectively with the contacts for the supply of electrical energy and which has at least one antenna. A transmitter-receiver connected to the at least one antenna is assigned to each radio module for signal- and data exchange between the components of the individual radio modules via the antennae thereof.

### BACKGROUND

The invention relates to an electronic subassembly according to the preamble of the main claim.

Current electronic systems comprise a large number of components, such as memories, microprocessors, digital signal processors, i.e. integrated circuits based on semiconductor material (subsequently termed semiconductor chip or chip), but also condensers, resistors, coils, filters, oscillator quartzes and the like which can be configured discretely or integrated on the semiconductor material. All these components are connected to each other generally via wide data buses of 16, 32 or 64 bit via a circuit carrier, for example a rigid printed circuit board. The constantly increasing number of electrical connections and contact points leads to ever greater problems with respect to reliability and yield. As a result of the demanded miniaturization, three-dimensional constructions must be kept in mind and taken into account, said three-dimensional constructions placing even higher requirements on the system design and in addition involving higher manufacturing costs.

### SUMMARY OF THE INVENTION

The object therefore underlying the invention is to produce an electronic subassembly, comprising a plurality of components which are connected to each other, in which the connection lines or data buses between the components are reduced to a large extent.

As a result of the fact that one or more components of the electronic subassembly are combined to form a separate radio module which is provided respectively with the contacts for the supply of electrical energy and which carries at least one antenna, a transmitter-receiver connected to the antenna being assigned to each radio module for signal- and data exchange between the components of the individual radio modules via the antennae thereof, a completely novel wireless connection concept is made available for producing electronic systems. Such a system comprises only simple robust modules which contain the electronic components, i.e. chips or a simple functional group. The modules thereby have only two contacts for the energy supply. The chips used contain, in addition to their intrinsic function such as memory, DSP, microprocessor etc., also a transmitter-receiver which can be integrated likewise and which produces a wireless data connection to the adjacent chips and hence replaces the spatially demanding data bus. As a result of the fact that so many data connections are no longer required because of the wireless radio connection, the chip can be mounted on a module which is slightly larger than the chip dimension. Hence a reduction in surface area is produced and the possibility of stacking modules three-dimensionally. As cited, the transmitter-receiver of the radio module is advantageously integrated in the semiconductor chip which contains the component or components, said semiconductor chip being able however to be configured also as a separate semiconductor chip which is connected in the module discretely to the component chip.

Advantageously, the frequency range of the radio modules is in the gigahertz range, the transmitting frequency being able to be on existing ISM bands (Industrial Scientific Medical), such as 17 GHz or 24 GHz, since there is no regulating there or only the transmitting power is limited. Advantageously, different frequency channels which are adjacent to each other are assigned to the radio modules.

It is particularly advantageous if the individual radio modules are cross-linked to each other, different networks being able to be used, for example the network structure can be WPAN, such as for example a ZigBee network.

The production of the required transmitter-receivers at these high frequencies is possible with modern CMOS technologies, for example those of 130 nm. In addition, the data rate can be increased when transmitting by means of adapted types of modulation so that several Gbit/s can be transmitted via a wireless connection according to the invention and hence a 64 bit bus can be replaced. The energy and spatial requirement of the transmitter-receivers is substantially less than the many driver circuits which are required to actuate a bus.

It is particularly advantageous that the radio modules are combined in a mechanically detachable manner, for example by means of plug-in devices. The construction technique according to the invention enables the exchange of components, which is an enormous advantage in complex systems, hence repairs or “upgrades” can be undertaken without difficulty. In current systems with exchangeable components, such as microprocessors and memories, very complicated sockets with a large number of pins must be fitted. In addition, the possibility is provided of reconfiguring a system on the software side during ongoing operation, i.e. connecting the individual modules in various ways in a wireless manner according to requirements.

The radio modules can however also be connected to each other in a mechanically fixed manner, for example via solder connections or electrically conductive adhesives, e.g. via contacts which are applied over the surface area, any three-dimensional structures which are beneficial for use then being able to be produced.

### BRIEF DESCRIPTION OF THE DRAWINGS

Embodiments of the invention are represented in the drawing and are explained in more detail in the subsequent description. There are shown:

FIG. 1, a schematic perspective view of a radio module and

FIG. 2, a plan view on an electronic subassembly corresponding to the present invention in schematic representation.

FIG. 3, a perspective view of a further radio module and an electronic subassembly, likewise shown in perspective.

### DETAILED DESCRIPTION OF THE INVENTION

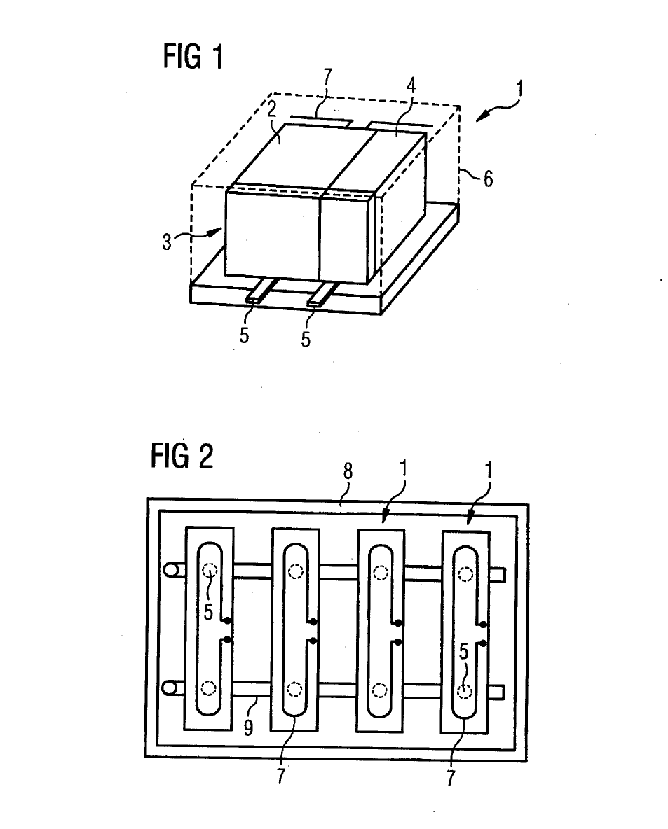

A radio module 1, as is used in the invention, is represented schematically in FIG. 1 and this can relate for example, as component, to a memory, a microprocessor or a digital signal processor or the like. The component 2 is configured as a semiconductor chip 3 and is produced for example corresponding to CMOS technology. The production of such semiconductor components 2 is generally known and is not dealt with in more detail.

In the represented embodiment according to FIG. 1, the semiconductor chip 3 also includes a transmitter-receiver 4 which is likewise integrated like the component 2. The semiconductor element 3 is provided with two schematically represented contacts 5 which are led out laterally and serve for current supply. These contacts can be very solid and hence have high reliability. The semiconductor chip 3 is mounted on or in a module carrier 6 in order to form the radio module 1, the module carrier being able to have a plate-like configuration or being able to be configured as a housing (illustrated in broken lines). The module carrier 6 which preferably comprises an electrically non-conductive material need be only slightly larger in its dimensions than the actual semiconductor element 3. The mechanical connection between the semiconductor element 3 and the module carrier 6 can be undertaken by gluing, soldering or the like. The electrical contacts 5 are likewise led out of the housing 6 as connections.

An antenna 7 (it can be a plurality) is assigned to the radio module 1, said antenna being configured for example as a dipole and being fitted as a copper foil on the surface of the module carrier 6 which is configured as a housing. The antenna 7 is connected to the transmitter-receiver 4 via corresponding antenna contacts and lines. Normally the radio module also includes resistors, condensers, coils, filters, oscillator quartzes (individually or as a plurality), these being able to be integrated on the semiconductor chip or configured as discrete components also. In the latter case the radio module has in addition some electrically printed or wire connections.

An electronic subassembly comprises a plurality of radio modules 1 which are illustrated in FIG. 1, the signal- or data exchange between the individual components of the subassembly being implemented in a manner corresponding to the connection via data buses in a radio transmission. The frequency range in which such a signal- and data transmission can take place optimally is prescribed by the dimensions of the antenna. In the present case, for example the edge length of the radio module 1, corresponding to FIG. 1, is two centimeters, i.e. the length of the dipole antenna 7 (λ/2) can likewise assume at most two centimeters, which leads to minimum transmitting frequencies (f=c/λ) of 15 GHz. For higher frequencies, the dipole antenna 7 is shorter and can be accommodated without difficulty on the module edges.

In FIG. 2, a schematic view of an electronic subassembly according to the invention is represented, said subassembly having a subassembly carrier 8 on which the plug strips 9 are mounted. The individual radio modules 1 are inserted by their contacts 5 into the plug strips 9 which represent an electrical connection, further additional mounting elements being able to be provided. The plug strips 9 are connected to a voltage source, not shown, so that all the radio modules 1 are supplied with current. The antennae 7 on the edges of the modules are represented purely schematically.

Such a subassembly corresponding to FIG. 2 can also be constructed in a network structure, network standards being used suitably. By way of example, reference is made inter alia to a WLAN (wireless local area network) or WPAN (wireless personal private area network).

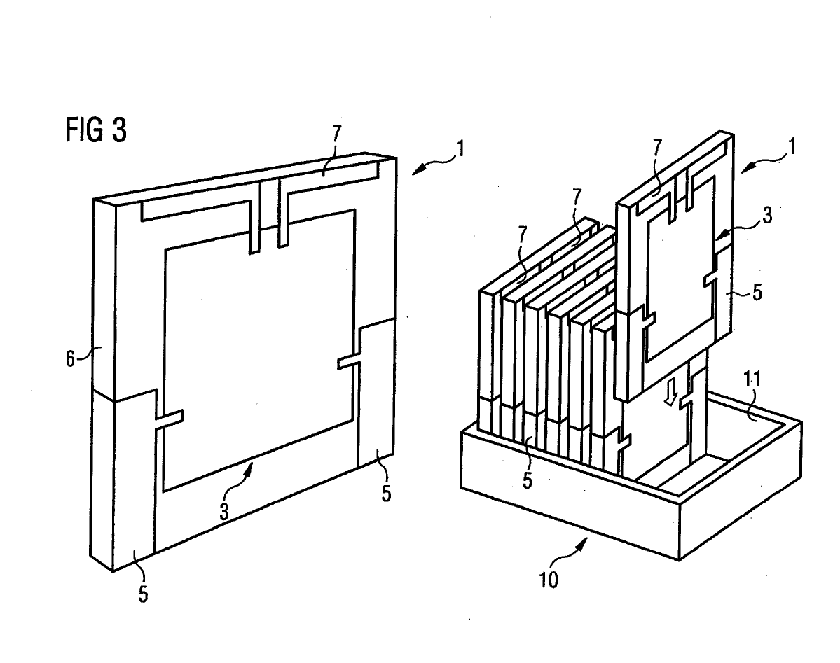

A further embodiment of a subassembly is represented in FIG. 3, there being, on the left, the cuboid radio module 1 with a semiconductor chip 3 contained in an encompassing module carrier 6, contacts 5 which are fitted laterally on the frame-like module carrier 6 and are connected to the semiconductor chip 3 and supply the voltage, and a dipole antenna 7 which is provided at the edge of the large surface of the module 1. Radio modules 1 of this type, standing on their flat end faces, are inserted in a box-like housing 10 which has contact faces 11 laterally on the inner walls, said contact faces being connected to the contacts 5 and serving for supplying voltage.

1. An electronic subassembly, comprising:
a plurality of components which are connected to each other at least partially for signal- and data exchange, said components having contacts for the supply of electrical energy,
wherein one or more components are combined to form a separate radio module which is provided, respectively, with contacts for the supply of electrical energy and which carries at least one antenna, a transmitter-receiver connected to the at least one antenna being assigned to each radio module for signal- and data exchange between the components of the individual radio modules via the antennae thereof.

2. The electronic subassembly according to claim 1, wherein the components are configured as semiconductor chips which are mounted on module carriers or in module housings.

3. The electronic subassembly according to claim 1, wherein a plurality of components are integrated in one semiconductor chip.

4. The electronic subassembly according to claim 1, wherein the transmitter-receiver of the radio module is integrated in the semiconductor chip which contains the component or components.

5. The electronic subassembly according to claim 1, wherein the transmitter-receiver is configured as a separate semiconductor chip which is connected discretely to the semiconductor chip which contains the component or components.

6. The electronic subassembly according to claim 1, wherein the radio modules are received in a housing or on a subassembly carrier.

7. The electronic subassembly according to claim 1, wherein the radio modules are combined in a mechanically detachable manner.

8. The electronic subassembly according to claim 1, wherein the radio modules are combined together securely by solder connections or electrically conductive adhesive connections.

9. The electronic subassembly according to claim 6, characterised in that the radio modules are combined by means of a plug-in device which provides electrical energy to the contacts of the radio modules.

10. The electronic subassembly according to claim 7, characterised in that the radio modules are combined by means of a plug-in device which provides electrical energy to the contacts of the radio modules.

11. The electronic subassembly according to claim 1, wherein the radio modules can be stacked three-dimensionally.

12. The electronic subassembly according to claim 1, wherein the at least one antenna of the radio module is configured as a dipole.

13. The electronic subassembly according to claim 1, wherein the transmission frequency of the radio modules is in the gigahertz range.

14. The electronic subassembly according to claim 1, wherein the semiconductor chips which contain the components and/or the transmitter-receivers are produced with using CMOS technology.

15. The electronic subassembly according to claim 1, wherein the individual radio modules are constructed to form a network structure.

16. The electronic subassembly according to claim 15, wherein the network is a WPAN.

17. The electronic subassembly according to claim 1, wherein different frequency channels are assigned to the radio modules.
